(19) United States
(12) Patent Application Publication
(10) Pub. No.: US 2018/0203308 A1
(43) Pub. Date: Jul. 19, 2018

(54) ARRAY SUBSTRATES AND DISPLAY PANELS

(71) Applicant: Shenzhen China Star Optoelectronics Technology Co., Ltd., Shenzhen, Guangdong (CN)

(72) Inventors: Zhichao ZHOU, Shenzhen, Guangdong (CN); YU-LIEN CHOU, Shenzhen, Guangdong (CN); Yue WU, Shenzhen, Guangdong (CN)

(73) Assignee: Shenzhen China Star Optoelectronics Technology Co., Ltd., Shenzhen, Guangdong (CN)

(21) Appl. No.: 15/117,444

(22) PCT Filed: Jul. 20, 2016
(86) PCT No.: PCT/CN2016/090654

§ 371 Date: Aug. 8, 2016

(30) Foreign Application Priority Data
Jul. 5, 2016 (CN) 201610524830.3

(51) Int. Cl. G02F 1/1343; G02F 1/1335; G02F 1/1368; H01L 27/12

(52) U.S. Cl. CPC G02F 1/134363; G02F 1/133514; H01L 27/1218; H01L 27/1225; G02F 1/1368

(57) ABSTRACT

The present disclosure relates to an array substrate and a display panel. The array substrate includes a substrate, a patterned middle layer arranged on the substrate, and a pixel electrode layer configured with no patterns being arranged on the patterned middle layer. The pixel electrode layer includes at least one protrusion area and at least one depressed area formed in accordance with the patterned middle layer. The array substrate may effectively resolve the dark-stripe issues.

### BACKGROUND OF THE INVENTION

### 1. Field of the Invention

The present disclosure relates to display technology, and more particularly to an array substrate and a display panel.

### 2. Discussion of the Related Art

With the development of display devices, the display devices may be divided into liquid crystal devices (LCDs), plasma display devices, and organic light emitting diode (OLED) devices.

Among the various display modes of LCDs, the vertical alignment (VA) display mode is popular due to great viewing angle. Generally, the design of VA display mode relates to multiple domains. There are two modes to realize the multiple domains, including PVA mode and MVA mode. With respect to the PVA mode, the cracks of the pixel electrodes form a lateral electrical field. With respect to the MVA mode, the protrusions within the pixel cell result in the multiple domain configuration of the liquid crystal molecules. However, both of the two modes, dark stripes may exist and the display performance is not good enough.

### SUMMARY

The present disclosure relates to one array substrate and a display panel to reduce the dark stripes on the display panel.

In one aspect, an array substrate includes: a substrate; a patterned middle layer is arranged on the substrate; a pixel electrode layer configured with no patterns is arranged on the patterned middle layer, and the pixel electrode layer includes at least one protrusion area and at least one depressed area formed in accordance with the patterned middle layer; the patterned middle layer is of stripe structures or of trench structures, and patterns of the middle layer is fish-bone-shaped; and the patterned middle layer is an active layer.

Wherein the trench structure includes recesses and protrusions, the depressed area of the pixel electrode layer is formed in accordance with the recess, and the protrusion area of the pixel electrode layer is formed in accordance with the protrusion.

Wherein the stripe structure includes cracks between blocks, the protrusion area of the pixel electrode layer is formed in accordance with the blocks, and the depressed area of the pixel electrode layer is formed in accordance with the cracks.

In another aspect, an array substrate includes: a substrate; a patterned middle layer is arranged on the substrate; and a pixel electrode layer configured with no patterns is arranged on the patterned middle layer, and the pixel electrode layer includes at least one protrusion area and at least one depressed area formed in accordance with the patterned middle layer.

Wherein the patterned middle layer is of stripe structures or of trench structures.

Wherein the trench structure includes recesses and protrusions, the depressed area of the pixel electrode layer is formed in accordance with the recess, and the protrusion area of the pixel electrode layer is formed in accordance with the protrusion.

Wherein the stripe structure includes cracks between blocks, the protrusion area of the pixel electrode layer is formed in accordance with the blocks, and the depressed area of the pixel electrode layer is formed in accordance with the cracks.

Wherein patterns of the middle layer is fish-bone-shaped.

Wherein the patterned middle layer is an active layer.

Wherein a passivation layer is configured between the active layer and the pixel electrode layer.

Wherein the active layer is made by amorphous silicon or indium gallium zinc oxide (IGZO).

In another aspect, a display panel includes: an array substrate includes a substrate, a patterned middle layer is arranged on the substrate, and a pixel electrode layer configured with no patterns is arranged on the patterned middle layer, and the pixel electrode layer includes at least one protrusion area and at least one depressed area formed in accordance with the patterned middle layer.

Wherein the patterned middle layer is of stripe structures or of trench structures.

Wherein the trench structure includes recesses and protrusions, the depressed area of the pixel electrode layer is formed in accordance with the recess, and the protrusion area of the pixel electrode layer is formed in accordance with the protrusion.

Wherein the stripe structure includes cracks between blocks, the protrusion area of the pixel electrode layer is formed in accordance with the blocks, and the depressed area of the pixel electrode layer is formed in accordance with the cracks.

Wherein patterns of the middle layer is fish-bone-shaped.

Wherein the patterned middle layer is an active layer.

Wherein a passivation layer is configured between the active layer and the pixel electrode layer.

Wherein the active layer is made by amorphous silicon or indium gallium zinc oxide (IGZO).

Wherein the display panel further includes a color filter substrate corresponding to the array substrate, and a liquid crystal layer between the array substrate and the color filter substrate. In view of the above, the array substrate includes a substrate, a patterned middle layer arranged on the substrate, and a pixel electrode layer configured with no patterns being arranged on the patterned middle layer. The pixel electrode layer includes at least one protrusion area and at least one depressed area formed in accordance with the patterned middle layer. As the pixel electrode layer is not configured with the patterns, such that no cracks exist. With such configuration, the issues, such as dark stripes, bad display brightness and contrastness, may not occur in the display panel adopting the array substrate.

### BRIEF DESCRIPTION OF THE DRAWINGS

FIG. 1 is a schematic view of the array substrate in accordance with a first embodiment.

FIG. 2 is a schematic view of the array substrate in accordance with a second embodiment.

FIG. 3 is a top view of the pixel electrode layer of FIG. 2.

FIG. 4 is a flowchart illustrating the manufacturing method of the array substrate of FIG. 2.

FIG. 5 is a schematic view of the display panel in accordance with one embodiment.

### DETAILED DESCRIPTION OF THE EMBODIMENTS

Embodiments of the invention will now be described more fully hereinafter with reference to the accompanying drawings, in which embodiments of the invention are shown.

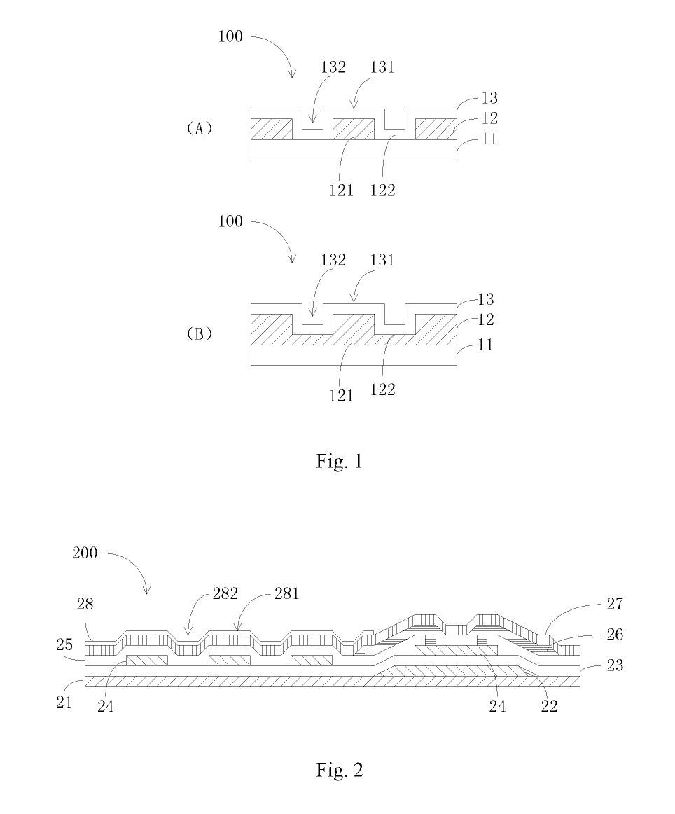

FIG. 1 is a schematic view of the array substrate in accordance with a first embodiment. Referring to FIG. 1, the array substrate 100 includes a substrate 11, a middle layer 12, and a pixel electrode layer 13.

The middle layer 12 is a patterned middle layer 12. That is, the manufacturing process of the middle layer 12 includes etching processes for forming the patterns. The pixel electrode layer 13 without patterns is formed on the middle layer 12. The pixel electrode layer 13 includes a protrusion area 131 and a depressed area 132 corresponding to the middle layer 12 with the patterns.

Specifically, the middle layer 12 may be of stripe structures (as shown in FIG. 1(A)), or the middle layer 12 may be of trench structures (as shown in FIG. 1(B)).

The middle layer 12 of the stripe structure may include blocks 121 and the cracks 122 formed between the blocks 121. That is, during the etching process, the middle layer 12 between the cracks 122 are removed completely. With respect to the middle layer 12, the protrusion area 131 is formed in accordance with the block 121, and the depressed area 132 is formed in accordance with the crack 122.

The middle layer 12 of the trench structure may include protrusions 121 and recesses 122. A thinner portion of the middle layer 12 remains to be the recesses 122. That is, only a portion of the middle layer 12 corresponding to the recesses 122 are removed. With respect to the thinner portion of the middle layer 12, the protrusion area 131 is formed in accordance with the protrusion 121, and the depressed area 132 is formed in accordance with the recess 122.

Regardless of the middle layer 12 of the stripe structure or the trench structure, the pixel electrode layer 13 forms the block electrodes having the protrusion areas 131 and the depressed areas 132. In this way, the liquid crystals within the display panel adopting the array substrate 100 may rotate, such that no dark stripes may be generated.

In real applications, other layers may be configured between the middle layer 12 and the pixel electrode layer 13. The pixel electrode layer 13 may be directly deposited on the middle layer 12, or the pixel electrode layer 13 may be indirectly deposited on the middle layer 12.

The array substrate includes the substrate, the patterned middle layer on the substrate, and the pixel electrode layer on the middle layer. the pixel electrode layer is not configured with the patterns. The middle layer includes recesses and the protrusions corresponding to the patterned middle layer, wherein the pixel electrode layer is not configured with the patterns, such that no cracks exist. With such configuration, the issues, such as dark stripes, bad display brightness and contrastness, may not occur in the display panel adopting the array substrate.

FIG. 2 is a schematic view of the array substrate in accordance with a second embodiment. The array substrate 200 includes a glass substrate 21, a gate 22, a gate insulation layer 23, an active layer 24, a blocking layer 25, a source/drain 26, a passivation layer 27, and a pixel electrode layer 28.

The active layer 24 is the patterned middle layer in the above embodiments. The pixel electrode layer 28 is arranged on the active layer 24, and the pixel electrode layer 28 includes at least one protrusion 281 and at least one recess 282. The active layer 24 is of the stripe structure or of the trench structure. Specifically, the pattern of the active layer 24 is of fish-bone-shaped. The corresponding protrusion 281 and the recess 282 also include the fish-bone-shaped patterns.

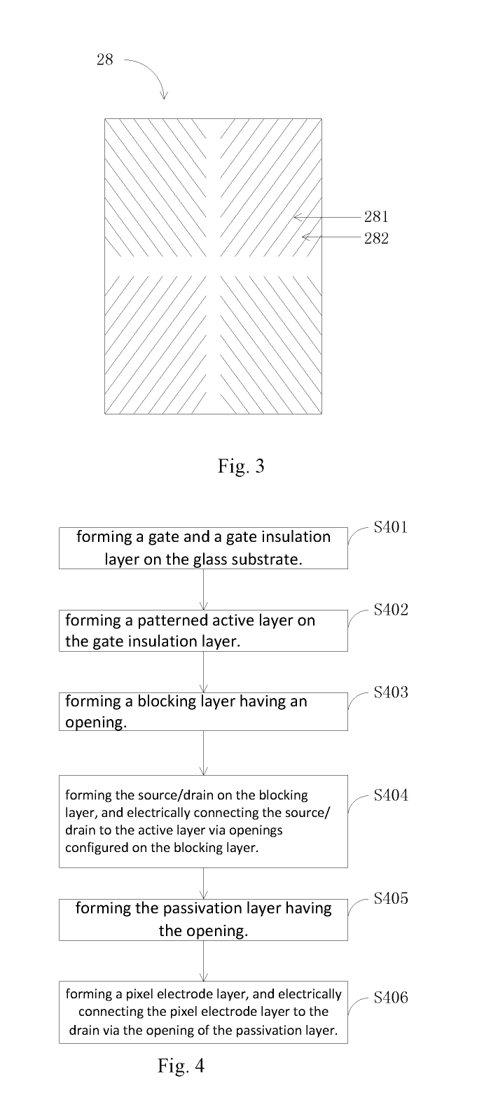

FIG. 3 is a top view of the pixel electrode layer of FIG. 2.

FIG. 4 is a flowchart illustrating the manufacturing method of the array substrate of FIG. 2. The manufacturing method may include the following steps.

In step S401, forming a gate and a gate insulation layer on the glass substrate.

Physical vapor deposition (PVD) or wet etching processes may be adopted to form the gate 22 on the glass substrate 21, and the chemical vapor deposition (CVD) or dry etching processes may be adopted to form the gate insulation layer 23.

In step S402, forming a patterned active layer on the gate insulation layer.

The step of forming the patterned active layer 24 on the gate insulation layer 23 relates to forming the active layer 24 in accordance with the display area of the array substrate such that the pixel electrode layer 28 corresponding to the active layer 24 is configured with the protrusion 281 and the recess 282. The patterned active layer 24 is of the stripe structure having fish-bone-shaped patterns. The active layer 24 may be made by amorphous silicon or indium gallium zinc oxide (IGZO).

In step S403, forming a blocking layer having an opening.

After the patterned active layer 24 is formed, the CVD and the dry etching processes are adopted to form the blocking layer 25. The blocking layer 25 is an etching-blocking layer 25. That is, the blocking layer 25 prevents the active layer 24 from being etched in the afterward etching processes. As the source/drain 26 has to be electrically connected to the active layer 24, two openings are configured on the blocking layer 25 such that the source and the drain may respectively contact with the active layer 24.

In block S404, forming the source/drain on the blocking layer, and electrically connecting the source/drain to the active layer via openings configured on the blocking layer.

The source and the drain are of the same metal, and thus may be formed at the same time in step S404. Specifically, the PVD is adopted to deposit one metal layer, and the wet etching process is adopted to pattern the metal layer so as to form the source and the drain. Upon depositing the metal layer, the metal layer may be deposited within the openings of the blocking layer 25 so as to electrically connect to the active layer 24.

In step S405, forming the passivation layer having the opening.

To delay the oxidation of the source/drain 26, the passivation layer 27 is formed. An opening is configured on the passivation layer 27 such that the pixel electrode layer 28 may be electrically connected to the drain. In this way, the pixel electrode layer 28 may contact with the drain via the opening. Specifically, the passivation layer 27 is formed by CVD and the dry etching process.

In step S406, forming a pixel electrode layer, and electrically connecting the pixel electrode layer to the drain via the opening of the passivation layer.

The pixel electrode layer 28 is formed by ITO via PVD. The ITO may be deposited within the opening of the passivation layer 27 so as to electrically connect to the drain.

As the active layer 24 is of the stripe structure, all of the blocking layer 25, the passivation layer 27, and the pixel electrode layer 28 have protrusions and recesses. With respect to the pixel electrode layer 28, the protrusion 281 is formed in accordance with the blocks of the active layer 24, and the recess 282 is formed in accordance with the cracks of the active layer 24.

In view of the above ,the pixel electrode layer 28 includes the protrusion 281 and the recess 282, and there is no crack. With such configuration, the issues, such as dark stripes, bad display brightness and contrastness, may not occur in the display panel adopting the array substrate.

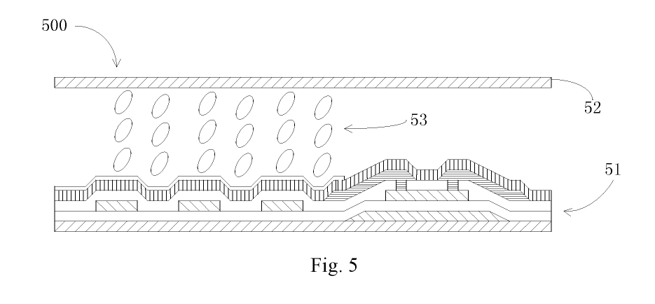

FIG. 5 is a schematic view of the display panel in accordance with one embodiment.

The display panel 500 includes an array substrate 51, a color filter substrate 52, and a liquid crystal layer 53.

The liquid crystal layer 53 is arranged between the array substrate 51 and the color filter substrate 52. In the embodiment, the array substrate 51 of the display panel 500 is similar to the array substrate 200 above.

In view of the above, the liquid crystal layer 53 may effectively rotate between the array substrate 51 and the color filter substrate 52, such that the issues, such as dark stripes, bad display brightness and contrastness, may not occur.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. An array substrate, comprising:
a substrate;
a patterned middle layer is arranged on the substrate;
a pixel electrode layer configured with no patterns is arranged on the patterned middle layer, and the pixel electrode layer comprises at least one protrusion area and at least one depressed area formed in accordance with the patterned middle layer;
the patterned middle layer is of stripe structures or of trench structures, and patterns of the middle layer is fish-bone-shaped; and
the patterned middle layer is an active layer.

2. The array substrate as claimed in claim 1, wherein the trench structure comprises recesses and protrusions, the depressed area of the pixel electrode layer is formed in accordance with the recess, and the protrusion area of the pixel electrode layer is formed in accordance with the protrusion.

3. The array substrate as claimed in claim 1, wherein the stripe structure comprises cracks between blocks, the protrusion area of the pixel electrode layer is formed in accordance with the blocks, and the depressed area of the pixel electrode layer is formed in accordance with the cracks.

4. An array substrate, comprising:
a substrate;
a patterned middle layer is arranged on the substrate; and
a pixel electrode layer configured with no patterns is arranged on the patterned middle layer, and the pixel electrode layer comprises at least one protrusion area and at least one depressed area formed in accordance with the patterned middle layer.

5. The array substrate as claimed in claim 4, wherein the patterned middle layer is of stripe structures or of trench structures.

6. The array substrate as claimed in claim 5, wherein the trench structure comprises recesses and protrusions, the depressed area of the pixel electrode layer is formed in accordance with the recess, and the protrusion area of the pixel electrode layer is formed in accordance with the protrusion.

7. The array substrate as claimed in claim 5, wherein the stripe structure comprises cracks between blocks, the protrusion area of the pixel electrode layer is formed in accordance with the blocks, and the depressed area of the pixel electrode layer is formed in accordance with the cracks.

8. The array substrate as claimed in claim 5, wherein patterns of the middle layer is fish-bone-shaped.

9. The array substrate as claimed in claim 4, wherein the patterned middle layer is an active layer.

10. The array substrate as claimed in claim 9, wherein a passivation layer is configured between the active layer and the pixel electrode layer.

11. The array substrate as claimed in claim 9, wherein the active layer is made by amorphous silicon or indium gallium zinc oxide (IGZO).

12. A display panel, comprising:
an array substrate comprises a substrate, a patterned middle layer is arranged on the substrate, and a pixel electrode layer configured with no patterns is arranged on the patterned middle layer, and the pixel electrode layer comprises at least one protrusion area and at least one depressed area formed in accordance with the patterned middle layer.

13. The display panel as claimed in claim 12, wherein the patterned middle layer is of stripe structures or of trench structures.

14. The display panel as claimed in claim 13, wherein the trench structure comprises recesses and protrusions, the depressed area of the pixel electrode layer is formed in accordance with the recess, and the protrusion area of the pixel electrode layer is formed in accordance with the protrusion.

15. The display panel as claimed in claim 13, wherein the stripe structure comprises cracks between blocks, the protrusion area of the pixel electrode layer is formed in accordance with the blocks, and the depressed area of the pixel electrode layer is formed in accordance with the cracks.

16. The display panel as claimed in claim 13, wherein patterns of the middle layer is fish-bone-shaped.

17. The display panel as claimed in claim 12, wherein the patterned middle layer is an active layer.

18. The display panel as claimed in claim 17, wherein a passivation layer is configured between the active layer and the pixel electrode layer.

19. The display panel as claimed in claim 17, wherein the active layer is made by amorphous silicon or indium gallium zinc oxide (IGZO).

20. The display panel as claimed in claim 12, wherein the display panel further comprises a color filter substrate corresponding to the array substrate, and a liquid crystal layer between the array substrate and the color filter substrate.
